(19) United States
(12) Patent Application Publication
(10) Pub. No.: US 2026/0351952 A1
(43) Pub. Date: Nov. 5, 2026

(54) METHODS AND APPARATUS FOR SOURCE MEASUREMENT UNIT (SMU) WITH OVER-VOLTAGE PROTECTION

(71) Applicant: Texas Instruments Incorporated, Dallas, TX (US)

(72) Inventors: Aditya Vighnesh Ramakanth Bommireddipalli, Tucson, AZ (US); Ramana Tadepalli, McKinney, TX (US)

(21) Appl. No.: 19/194,788

(22) Filed: Apr. 30, 2025

(51) Int. Cl. H02H 3/20; G01R 19/00; G01R 31/28; H03F 3/04

(52) U.S. Cl. CPC H02H 3/20; G01R 19/0038; G01R 31/2851; H03F 3/04

(57) ABSTRACT

An example apparatus includes an amplifier having an input and an output; a voltage pin; an output pin; protection circuitry having an input, a terminal, and an output, the input of the protection circuitry coupled to the output of the amplifier, the terminal of the protection circuitry coupled to the voltage pin, and the output of the protection circuitry coupled to the output pin; sense circuitry having an input coupled to a pin of the integrated circuit and an output coupled to the input of the amplifier.

### TECHNICAL FIELD

This description relates generally to source measurement units and, more particularly, to methods and apparatus for source measurement units with over-voltage protection.

### BACKGROUND

Device test systems provide signals having different types of electrical characteristics to a device under test (DUT). For example, source measurement units (SMUs) may subject a DUT to force voltage input signals, force current input signals, and other types of electrical characteristics to test one or more DUTs, for instance prior to sale or distribution.

### SUMMARY

For methods and apparatus for a source measurement unit (SMU) with over-voltage protection, an example integrated circuit includes an amplifier having an input and an output; a voltage pin; an output pin; protection circuitry having an input, a terminal, and an output, the input of the protection circuitry coupled to the output of the amplifier, the terminal of the protection circuitry coupled to the voltage pin, and the output of the protection circuitry coupled to the output pin; sense circuitry having an input coupled to a pin of the integrated circuit and an output coupled to the input of the amplifier. Other examples are described.

For methods and apparatus for a source measurement unit (SMU) with over-voltage protection, an example integrated circuit includes a first amplifier having an input and an output; a voltage pin and an output pin; a diode having an anode and a cathode, the cathode of the diode coupled to the voltage pin; a second amplifier having a first input, a second input, and an output, the first input of the second amplifier coupled to the anode of the diode and to the output of the first amplifier, the second input of the second amplifier coupled to the output of the second amplifier, and the output of the second amplifier coupled to the output pin; and sense circuitry having an input coupled to a pin of the integrated circuit and an output coupled to the input of the first amplifier. Other examples are described.

For methods and apparatus for a source measurement unit (SMU) with over-voltage protection, an example integrated circuit having a first voltage pin, a second voltage pin, an output pin, and a sense pin includes a first amplifier having an input and an output; a first amplifier having an input and an output; a first diode having an anode and a cathode, the cathode of the first diode coupled to the first voltage pin; a second diode having an anode and a cathode, the anode of the second diode coupled to the second voltage pin and the cathode of the second diode coupled to the anode of the first diode; a second amplifier having a first input, a second input, and an output, the first input of the second amplifier coupled to the anode of the first diode, to the cathode of the second diode, and to the output of the first amplifier, the second input of the second amplifier coupled to the output of the second amplifier, and the output of the second amplifier coupled to the output pin; current sense circuitry having an input and an output, the input of the current sense circuitry coupled to the output of the second amplifier, the output of the current sense circuitry coupled to the output pin; and voltage sense circuitry having an input and an output, the input of the voltage sense circuitry coupled to the sense pin, the output of the voltage sense circuitry coupled to the input of the first amplifier. Other examples are described.

### BRIEF DESCRIPTION OF THE DRAWINGS

FIG. 1 is a block diagram of an example source measurement unit (SMU) including an example device under test (DUT) protection circuitry to test electrical devices.

FIG. 2 is an example block diagram of an example SMU, or a portion thereof, that includes the DUT protection circuitry of FIG. 1.

FIG. 3 is a schematic of an example first implementation of the DUT protection circuitry of FIG. 2.

FIG. 4 is a schematic of an example second implementation of the DUT protection circuitry of FIG. 2.

FIG. 5 is a schematic of an example third implementation of the DUT protection circuitry of FIG. 2.

FIG. 6 is a flowchart representative of example operations that may be performed by the DUT protection circuitry of FIG. 2.

The drawings are not necessarily to scale. Generally, the same reference numbers in the drawing(s) and this description refer to the same or similar (functionally and/or structurally) features and/or parts. Although the drawings show regions with clean lines and boundaries, some or all of these lines and boundaries may be idealized. In reality, the boundaries or lines may be unobservable, blended or irregular.

### DETAILED DESCRIPTION

Source measurements units (SMUs) are used in integrated circuit (IC) testing equipment to force and measure voltage and current on device under test (DUT) pins. As used herein, forcing a voltage or a current means to actively apply a specific, predetermined voltage or current, or a controlled sequence of voltages and/or currents to a DUT to observe how the DUT reacts under that controlled sequence of voltages and/or currents. DUT pins are points at an input and an output of the electrical device being tested that connect to the input and output of the SMU. In some examples, DUT pins illustrated herein may be partial sections of more complex DUT integrated circuits with multiple pins. SMUs support a range of voltages (e.g., 6V to 200V) to allow testing a wide range of pin functionality. For example, an SMU supports forcing and measuring voltage and current of a 6V rated electrical device and supports forcing and measuring voltage and current of a 200V rated device. In some examples, SMUs are manufactured as integrated system-on-chips (SoCs) to allow for high channel density. For example, an SMU manufactured as an integrated SoC may have a number of independent measurement channels integrated onto one chip, where each of the measurement channels enable simultaneous measurements on different points in an electrical device.

However, when an SMU is used to test DUTs having a lower voltage rating, the low absolute maximum rating of the DUT makes the DUT prone to inadvertent electrical over-voltage stress (EOS). EOS is a state in which the DUT is subjected to undesirable voltage, current, or power. An SMU potentially creates EOS by setting incorrect clamp limits in the SMU. For example, an SMU creates EOS by clamping the maximum force voltage to a voltage higher than the lower absolute maximum rating of the DUT. In some examples, EOS occurs when there is a wiring fault between the SMU and DUT, such as an open Kelvin connection, which is a sense wire used for accurately measuring voltage of the DUT without interference from current carrying wires. An open Kelvin connection is when the sense wire is not making contact with the DUT, essentially creating an open-circuit. In such scenarios, EOS can cause permanent damage to the DUT, which reduces a yield of the DUT and increases costs of manufacturing.

To reduce and eliminate EOS, SMUs include hardware and firmware clamps that prevent the force voltage from exceeding a clamp voltage. For example, line protectors, diode clamps, firmware clamps, and firmware clamps plus hardware open sense detect switches are all circuitry added to the SMU to prevent the DUT from experiencing EOS. However, none of these hardware and firmware clamping mechanisms allow the SMU to safely test an electrical device below a supply of the SMU system. For example, the supply of the SMU system is the voltage supplied to the hardware for proper operation of the hardware. In the firmware clamp plus hardware open sense detect switches, a force amplifier is driven by programmable circuitry to force an output voltage to a DUT, and a comparator is used to detect if a sense wire (e.g., a Kelvin connection) becomes disconnected from the DUT. The force amplifier and the comparator in the above example require a supply voltage to operate (e.g., 6V for headroom). That supply voltage is the supply voltage of the SMU system.

In some examples, when the DUT has a 1-2V maximum rating, the protection for the DUT is to be lower than the supply voltage. The hardware clamps may not provide that protection. In some examples, however, the firmware clamps can. For example, firmware clamps can provide a low voltage to the force amplifier, which can provide the low voltage to the DUT. In some examples where the firmware becomes disabled or incorrectly programmed, there are no protection mechanisms for that DUT with a 1-2V maximum rating with the SMU requiring voltage supplies beyond the safe DUT voltage.

Examples described herein provide a device under test (DUT) protection circuitry that protects electrical devices with a low maximum voltage rating relative to the supply voltage of the SMU. The DUT protection circuitry described herein is coupled to a protection voltage supply pin that is external to the SMU supply voltage. The protection voltage supply pin allows limits of the SMU to be set externally. In examples described herein, the DUT protection circuitry is implemented by diode clamps and a unity gain buffer. In some examples described herein, the DUT protection circuitry is implemented by comparators and a unity gain buffer. The different implementations of the DUT protection circuitry force an output voltage of the SMU to be set to a desired protection voltage, depending on the DUT, when the sense wire has been disconnected or the firmware clamps configure the force voltage incorrectly.

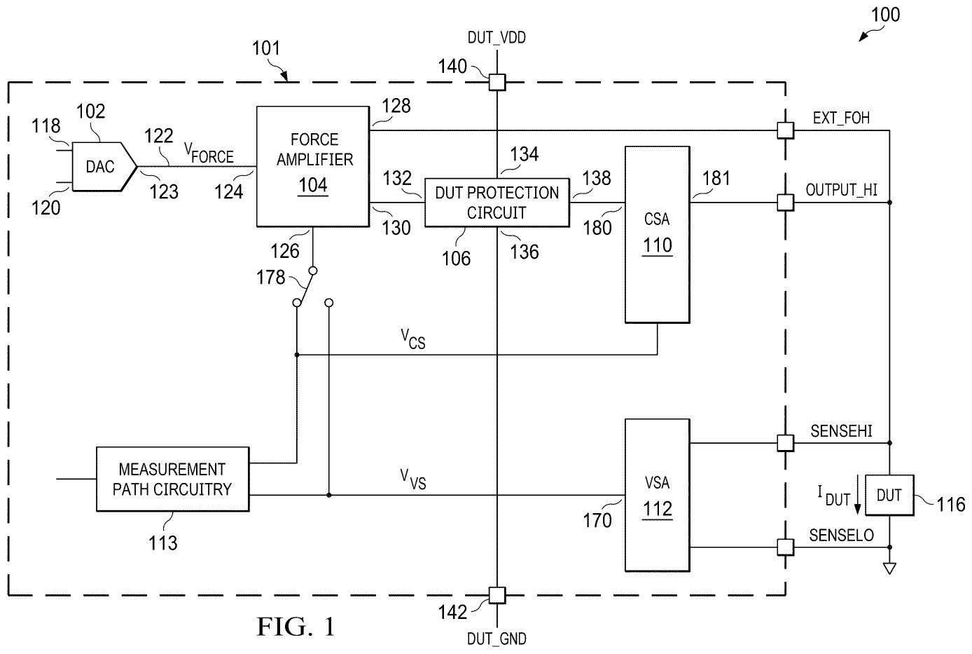

FIG. 1 is a block diagram of an example testing environment 100 that includes a source measurement unit (SMU) 101. In some examples, circuitry of SMU 101 are implemented on a single integrated circuit (IC) and may be coupled to a device under test (DUT) 116. In other examples, circuitry of the SMU 101 are included in multiple ICs.

The SMU 101 of FIG. 1 includes one channel. A channel includes circuitry for forcing an electrical characteristic to a single DUT and responsively measuring an electrical characteristic of the DUT. In another example, a SMU includes two or more channels, in which case, the SMU may be referred to as a parametric measurement unit (PMU). Multiple channels may be used in coordination to force voltage or current to one or more DUTs. Herein, channel and SMU channel are used interchangeably. In an example, the SMU 101 can be set to a force voltage mode to provide a controlled or substantially controlled voltage to the DUT 116 or a force current mode to provide a controlled or substantially controlled current to the DUT 116. Further to this example, the SMU 101 can be set to a current measure mode or a voltage measure mode to, respectively, measure a current or a voltage at the DUT 116. Various switches in the SMU 101 may be opened and closed (for instance using a controller that is not shown) to set the mode of the SMU 101.

In the example of FIG. 1, the SMU 101 includes digital-to-analog (DAC) circuitry 102 having a first input 118 and a second input 120. The DAC 102 converts digital values indicative of a target value to corresponding analog values, in which the DAC 102 may be implemented using analog circuitry including multiple amplifiers, comparators, switches, and resistors. The first input 118 and the second input 120 receive digital input signals corresponding to target force voltage values (V_{FORCE}) 122 and offset values at a first output 123. The SMU 101 includes an example force amplifier (FA) 104 having a first input 124, a second input 126, a first output 128 and a second output 130. The first input 124 of the FA 104 is coupled to the output 123 of the DAC circuitry 102 to allow target voltage force values to be set at the DUT 116 at target load current values.

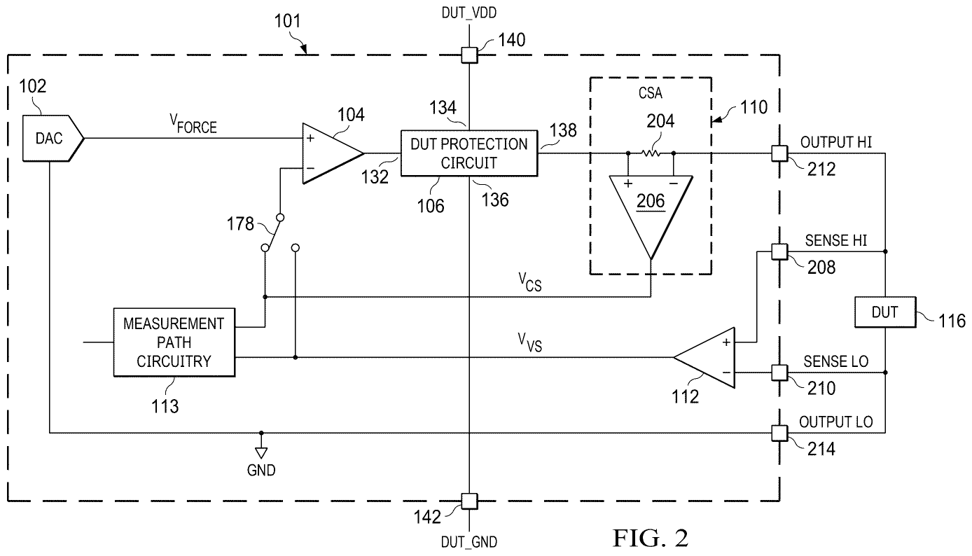

The SMU 101 includes a DUT protection circuitry 106 having a first input 132, a second input 134, a third input 136, and an output 138. The first input 132 of the DUT protection circuitry 106 is coupled to the second output 130 of the FA 104. The second input 134 of the DUT protection circuitry 106 is coupled to a first voltage pin 140. The third input 136 of the DUT protection circuitry 106 is coupled to a second voltage pin 142. The DUT protection circuitry 106 is to clamp a voltage at the output 138 of the DUT that is controlled (e.g., limited) by an external voltage. The first voltage pin 140 and the second voltage pin 142 receive that external voltages and supplies the external voltages to the DUT protection circuitry 106. As used herein, the external voltage is a voltage that is external to or different from the supply voltage of the SMU 101. For example, the first voltage pin 140 may be connected to the power supply of the DUT 116, which is different than the power supply of the SMU 101. The DUT protection circuitry 106 is described in further detail below in connection with FIGS. 2-5.

The SMU 101 includes a current sense amplifier (CSA) 110 having a bidirectional current path between an first node 180 and a second node 181, and having a an output (V_{CS}). The CSA 110 measures current values and may be implemented using analog circuitry including multiple amplifiers, comparators and resistors. The first node 180 of the CSA 110 is coupled to the output 138 of the DUT protection circuitry 106. The second node 181 of the CSA 110 is coupled to DUT 116 at an OUTPUT_HI node. The second node 181 of the CSA 110 provides information of the currents flowing to/from the DUT 116.

The SMU 101 includes a voltage sense amplifier (VSA) 112 having a first input, a second input, and an output. The VSA 112 measures voltage values and may be implemented using analog circuitry including multiple amplifiers, comparators and resistors. The first input and the second input of the VSA 112 are coupled to the DUT 116 to measure voltage values across the DUT 116.

The SMU 101 includes measurement path circuitry 113 having a first input, a second input, and an output. The measurement path circuitry 113 performs analysis functions corresponding to devices under test and may be implemented using processor circuitry and analog circuitry including multiple amplifiers, comparators and resistors. The first input of the measurement path circuitry 113 is coupled to the second output (V_{CS}) of the CSA 110 and the second input of the measurement path circuitry 113 is coupled to the output of the VSA 112. The measurement path circuitry 113 includes any number of sub-circuits to facilitate, in part, voltage scaling, measurement path filtering, and diagnosis multiplexing for the measured voltages and currents from the CSA 110 and the VSA 112. The output of the measurement path circuitry 113 may be analog or digital.

The SMU 101 includes a force voltage and current switch 178 to control whether the SMU 101 operates in the force voltage mode or the force current mode. A force voltage mode means that the SMU 101 actively provides a specific voltage or sequence of specific voltages to the DUT 116. A force current mode means that the SMU 101 actively provides a specific current or a sequence of currents to the DUT 116. Either voltage across the DUT 116 or current through the DUT 116 or both can be measured while forcing either current or voltage, depending on how the measurement path circuity 113 is designed.

FIG. 2 is an example schematic diagram of the SMU 101, or a portion thereof, that includes the DUT protection circuitry 106 of FIG. 1. In some examples, the DUT protection circuitry 106 may be referred to as “protection circuitry”. The SMU 101 of FIG. 2 includes the DAC 102, the FA 104, the DUT protection circuitry 106, the current sense amplifier circuitry 110, the voltage sense amplifier (VSA) 112, the DUT 116, the measurement path circuitry 113, and the example force voltage/current switch 178. In some examples, the current sense amplifier circuitry 110 may be referred to as “sense circuitry” and “current sense circuitry”. In some examples, the voltage sense amplifier 112 may be referred to as “voltage sense circuitry”. The current sense amplifier circuitry 110 includes an example resistor 204 and an example current sense amplifier 206. The SMU 101 also include a first sense pin 208, a second sense pin 210, a first output pin 212, and a second output pin 214. As mentioned above, the pins illustrated herein may be partial sections of more complex DUT integrated circuits with multiple pins.

In FIG. 2, the DAC 102 includes an input and an output. The DAC 102 may be programmed by firmware to convert digital values, indicative of a target value, corresponding to analog values. In some examples, the DAC 102 is programmed to convert incorrect digital values. For example, an error may occur at an operator/programmer end of the firmware, causing the DAC 102 to provide analog values exceeding a maximum voltage rating of the DUT 116.

In FIG. 2, the FA 104 includes a first input, a second input, and an output. The first input of the FA 104 is coupled to the output of the DAC 102. The FA 104 supplies a voltage to the DUT 116 in an effort to reach a target DUT voltage value.

In FIG. 2, the DUT protection circuitry 106 includes the first input 132, the second input 134, the third input 136, and the output 138. The first input 132 of the DUT protection circuitry 106 is coupled to the output of the FA 104, the second input 134 of the DUT protection circuitry 106 is coupled to the first voltage pin 140, and the third input 136 of the DUT protection circuitry 106 is coupled to the second voltage pin 142. In some examples, the second input 134 is a terminal of the DUT protection circuitry 106. The DUT protection circuitry 106 limits the output signal of the FA 104 (e.g., the signal on the input 132 of DUT protection circuitry 106) to an external protection voltage between the voltages set at the first voltage pin 140 and the second input 142. For example, the DUT protection circuitry 106 clamps a force voltage (V_{FORCE}) at the input 132 of the DUT protection circuitry 106 when the force voltage begins to rise to or exceed the protection voltage set on first voltage pin 140. Conversely if the voltage (V_{FORCE}) begins to drop below the protection voltage set on second voltage pin 142, the DUT protection circuit 106 prevents any voltage drop below the voltage set on second voltage pin 142.

In FIG. 2, the resistor 204 of the sense circuitry 110 includes a first terminal and a second terminal. The first terminal of the resistor 204 is coupled to the output 138 of DUT protection circuitry 106 and the second terminal of the resistor 204 is coupled to the first output pin 212. An input of the DUT 116 is coupled to the first output pin 212. The current sense amplifier 206 of the sense circuitry 110 includes a first input, a second input, and an output. The first input of the current sense amplifier 206 is coupled to the first terminal of the resistor 204 and the second input of the current sense amplifier 206 is coupled to the second terminal of the resistor 204. In operation, the current sense amplifier 206 reads the current across the resistor 204 to sense the current of the DUT 116. The CSA 110 and its resistor 204 may be placed either before or after the DUT protection circuit 106 depending on other desired performance parameters of the SMU 101.

In FIG. 2, the voltage sense circuitry 112 (VSA 112) includes a first input, a second input, and an output. The first input of the VSA 112 is coupled to the first sense pin 208 (SENSE_{HI}) and the second input of the VSA 112 is coupled to the second sense pin 210 (SENSE_{LO}). The first sense pin 208 is coupled to the input of the DUT 116 and the second sense pin 210 is coupled to the output of the DUT 116, together sensing the voltage across the DUT. In operation, the voltage sense circuitry 112 measures the voltage of the DUT 116 by reading (e.g., sensing) the voltage at the first sense pin 208 (SENSE_{HI}) and the second sense pin 210 (SENSE_{LO}). In some examples, the first sense pin 208 becomes disconnected from the DUT 116. Disconnection of the sense pin 208 from the DUT 116 can cause the output of the FA 104 to move arbitrarily between the supply levels of the SMU 101 due to the feedback loop being broken. In cases where there is no protection circuit, or where a programmable protection is unprogrammed, the output of the FA 104 would exceed the safe operating region of the DUT 116 either in the positive or in the negative direction. As the output of the VSA circuitry 112 changes, it is limited to the voltage set by the external protection voltages, which are set to values that bound to voltages that the DUT 116 can handle (e.g., the maximum voltage rating of the DUT 116). As such, the DUT 116 does not experience EOS (e.g., Electrical Over Stress) due to the open-circuit failure of the sense line (SENSE_{HI}) or of the sense line (SENSE_{LO}). The disconnection of the SENSE_{LO} has an identical impact on the behavior of the SMU 101 as the disconnection of SENSE_{HI}.

In FIG. 2, the measurement path circuitry 113 includes a first input, a second input, and an output. The first input of the measurement path circuitry 113 is coupled to the first output of the CSA 110. The second input of the measurement path circuitry 113 is coupled to the output of the voltage sense circuitry 112. The output of the measurement path circuitry 113 is structured to be coupled to programmable circuitry for analysis of the current and voltage of the DUT 116.

In FIG. 2, the force voltage/current switch 178 includes a first input, a second input, and an output. The first input of the force voltage/current switch 178 is coupled to the output of the current sense amplifier 206 and to the first input of the measurement path circuitry 113, the second input of the force voltage/current switch 178 is coupled to the output of the voltage sense circuitry 112 and to the second input of the measurement path circuitry 113, and the output of the force voltage/current switch 178 is coupled to the second input of the FA 104. In operation, the output signal of the force voltage/current switch 178 switches between the first input and the second input of the force voltage/current switch 178 to control whether the output signal of the current sense amplifier 206 or the output signal of the voltage sense circuitry 112 is directed to the second input of the FA 104. In some examples, the measurement path circuitry 113 contains analog to digital conversion systems and includes the switch 178. In such examples, the information supplied in feedback to the force amplifier (FA) 104 at its second input (e.g., inverting input) may be included in the information forced by the DAC 102 at the first input (e.g., non-inverting input) instead. The DUT protection circuit 106 remains unchanged in these cases, and functions in an identical manner to the description above.

As described in further detail below, the DUT protection circuitry 106 prevents EOS on the DUT 116 independent of kelvin failures (e.g., open-circuit sense faults) or firmware errors. The DUT protection circuitry 106 does not have any off-chip components and, thus, has minimum cost overhead, lower leakage, and lower board parasitics compared to external hardware clamps (e.g., line protectors, etc.) The protection provided by DUT protection circuitry 106 naturally scales with absolute maximum voltage rating of the DUT 116 when connected to a power supply of the DUT 116. The DUT protection circuitry 106 is independent of firmware, preventing inadvertent errors due to incorrectly or inaccurately programmed firmware.

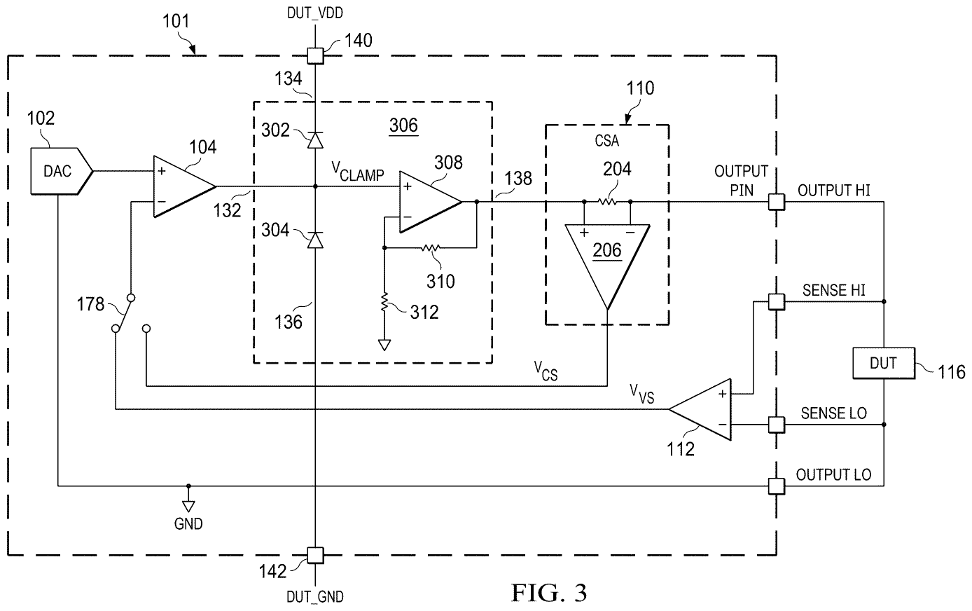

FIG. 3 is a schematic of an example first implementation of the DUT protection circuitry 106 of FIG. 2. In the example of FIG. 3, the SMU 101 includes the DAC 102 of FIG. 1, the FA 104 of FIG. 1, the current sense circuitry 110 of FIG. 1, the voltage sense circuitry 112 of FIG. 1, the DUT 116 of FIG. 1, the force voltage/current switch 178 of FIG. 1, and an example DUT protection circuitry 306. The DUT protection circuitry 306 of FIG. 3 includes an example first diode 302, an example second diode 304, and an example amplifier 308.

The first diode 302 of FIG. 3 includes an input (anode) and an output (cathode), the second diode 304 of FIG. 3 includes an input (anode) and an output (cathode), and the amplifier 308 of FIG. 3 includes a first input, a second input, and an output. The input of the first diode 302 is coupled to the output of the FA 104 at a V_{CLAMP} node. The output of the first diode 302 is coupled to first voltage pin 140. The output of the second diode 304 is coupled to the output of the FA 104 and to the input of the first diode 302 at the V_{CLAMP} node. The first input (+) of the amplifier 308 is coupled to the output of the FA 104, to the input of the first diode 302, and to the output of the second diode 304, at the V_{CLAMP} node. The second input (−) of the amplifier 308 is coupled to the output of the amplifier 308. In some examples, a first resistor 310 is coupled between the second input (−) of the amplifier 308 and the output of the amplifier 308. Additionally, a second resistor 312 is coupled between the second input (−) of the amplifier 308 and ground. The output of the amplifier 308 is coupled to the output pin 212.

The first diode 302 and the second diode 304 operate to conduct current and redirect excess voltage, at the output of the FA 104, away from the input to the DUT 116. For example, the first diode 302 and the second diode 304 form a voltage clamp (e.g., a transient voltage suppressor). A diode conducts current when a positive voltage is applied to an anode terminal (e.g., input of the diode 302 and the input of the diode 304) relative to the voltage at a cathode (e.g., output of the diode 302 and output of the diode 304).

The amplifier 308 operates as a power stage to the FA 104, where the amplifier 308 increases the output signal of the FA 104 and prevents the FA 104 from being loaded by DUT 116. In some examples, the amplifier 308 is a unity gain buffer (e.g., a voltage follower, a voltage buffer, etc.) that has a gain of two, the gain of two generated by the first resistor 310 and second resistor 312. The first and second diodes 302, 304 clamp a voltage at the first input (+) of the amplifier 308 so that the output signal of the amplifier 308 does not exceed the maximum rating of the DUT 116 (e.g., the external protection voltages).

In an example operation of the DUT protection circuitry 106 of FIG. 3, assume the maximum voltage rating of the DUT 116 is +1.8V/−1.0V, the supply voltage of the SMU 101 is 8V, and the FA 104 has a gain of 2 and ±6V of headroom. With a maximum voltage rating of +1.8V, the first voltage pin 140 is set to 1.2V, and the second voltage pin 142 is set to −0.4V. For example, an external supply voltage supplies 1.2V at the first voltage pin 140, and another supplies −0.4V at the second voltage pin 142.

In the example operation, the DAC 102 incorrectly provides a 2V analog signal to the FA 104. The FA 104 drives 4V (e.g., 2V input signal times gain of 2) to the first input 132 of the DUT protection circuitry 306. The first diode 302 begins conducting current when 4V is at the first input 132, because the voltage at the output of the first diode 302 is set to 1.2V. For example, when the voltage at the input of the first diode 302 exceeds the voltage at the output of the first diode 302, the first diode 302 turns on and conducts current. When the first diode 302 turns on, the first diode 302 sends the excess current to the first voltage pin 140, causing V_{CLAMP} to not exceed 1.8V (e.g., external protection voltage +0.6V diode drop). The first voltage pin 140 passes the extra (e.g., excess) current to ground in order to keep the potential difference between external protection voltage and ground at 1.2V.

In another example, the DAC 102 incorrectly provides a −1V analog signal to the FA 104. The FA 104 drives −2V (e.g., 1V input signal times gain of 2) to the first input 132 of the DUT protection circuitry 306. The second diode 304 begins conducting current when −2V is at the first input 132, because the input of the second diode 304 is set to −0.4V. For example, when the voltage at the output of the second diode 304 drops below the voltage at the input of the second diode 304 (e.g., −1V>−0.4V), the second diode 304 turns on and conducts current. When the second diode 304 turns on, the second diode 304 sends the current to the V_{CLAMP} node, thereby increasing the voltage at the V_{CLAMP} node and not allowing it to drop below −1.0V (e.g., external protection voltage +−0.6V diode drop). In some examples, the first diode 302 and the second diode 304 are implemented by precision diodes to remove the voltage drop across the first diode 302 and the second diode 304.

The first implementation of the DUT protection circuitry 306 is an open-loop diode based clamp that provides a high speed response time (e.g., less than 1 microsecond). The first implementation of the DUT protection circuitry 306 is stable irrespective of load, due to the implementation of the resistor 204 isolating the load from the amplifier 308 (e.g., the unity gain buffer). The first implementation of the DUT protection circuitry 306 is smaller and power efficient relative to a continuous-time high-speed comparator with programmable thresholds. For example, a continuous-time high-speed comparator may be used to sense that the voltage at SENSE_{HI} node is abnormally high and then cut off current to the DUT to protect the DUT from EOS. However, the continuous-time high-speed comparator has a slow reaction time, resulting in the DUT already experiencing EOS before the continuous-time high-speed comparator can cut off the high current. The first implementation of the DUT protection circuitry 306 is more power efficient than such a continuous-time high-speed comparator because the diodes 302, 304 do not consume any power when not active. Comparators would always need to be biased and, thus, continuously consume power. Also, comparators may have particular speed requirements, meaning that comparators use more current than the amplifier 308.

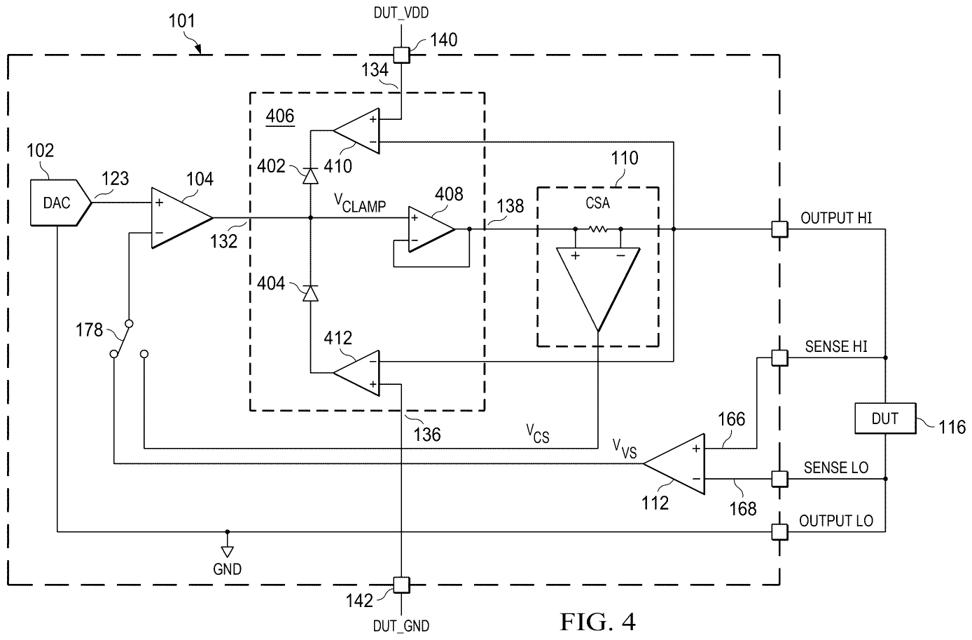

FIG. 4 is a schematic of an example second implementation of the DUT protection circuitry 106 of FIG. 2. In the example of FIG. 4, the SMU 101 includes the DAC 102 of FIG. 1, the FA 104 of FIG. 1, the current sense circuitry 110 of FIG. 1, the voltage sense circuitry 112 of FIG. 1, the DUT 116 of FIG. 1, the force voltage/current switch 178 of FIG. 1, and an example DUT protection circuitry 406. The DUT protection circuitry 406 of FIG. 4 includes an example first diode 402, an example second diode 404, an example amplifier 408, an example first comparator 410, and an example second comparator 412.

The first diode 402 of FIG. 4 includes an input (anode) and an output (cathode), the second diode 404 of FIG. 4 includes an input (anode) and an output (cathode), and the amplifier 408 of FIG. 4 includes a first input, a second input, and an output. The first comparator 410 includes a first input, a second input, and an output. The second comparator 412 includes a first input, a second input, and an output.

The input of the first diode 402 is coupled to the output of the FA 104 at a V_{CLAMP} node. The output of the first diode 402 is coupled to the output of the first comparator 410. The first input (+) of the first comparator 410 is coupled to the first voltage pin 140 and the second input (−) of the first comparator 410 is coupled to the output (OUTPUT_{HI}) of the sense circuitry 110. The input of the second diode 404 is coupled to the output of the second comparator 412. The output of the second diode 404 is coupled to the output of the FA 104 and to the input of the first diode 402 at the V_{CLAMP} node. The first input (+) of the second comparator 412 is coupled to second voltage pin 142, and the second input (−) of the second comparator 412 is coupled to the output (OUTPUT_{HI}) of the sense circuitry 110 and to the second input (−) of the first comparator 410. The first input (+) of the amplifier 408 is coupled to the output of the FA 104, to the input of the first diode 402, and to the output of the second diode 404, at the V_{CLAMP} node. The second input (−) of the amplifier 408 is coupled to the output of the amplifier 408. The output of the amplifier 408 is coupled to the output pin 212.

The second implementation of the DUT protection circuitry 406 operates to sense a voltage at the output pin 212 (OUTPUT_{HI}) and clamp that voltage to the voltage set by the external protection voltage (e.g., the voltage at the first voltage pin 140 and the voltage at the second voltage pin 142). The amplifier 408 operates as a power stage to the FA 104, where the amplifier 408 buffers the output signal of the FA 104 and prevents the FA 104 from being loaded by DUT 116. In some examples, the amplifier 408 is a unity gain buffer (e.g., a voltage follower, a voltage buffer, etc.) that has a gain of one.

The first input (+) of the first comparator 410, and the first input (+) of the second comparator 412 are voltage setpoints, set by the first voltage pin 140 and second voltage pin 142, respectively. As such, when the first comparator 410 determines that the voltage at output pin 212 (OUTPUT_{HI}) is greater than the voltage at the first voltage pin 140, the first comparator 410 provide a low voltage signal (e.g., 0V) to the output of the first diode 402. In some examples, this low voltage signal causes the first diode 402 to turn on and conduct current, thereby decreasing the voltage at V_{CLAMP}, which decreases an output signal of the amplifier 408 and, thus, decreases the voltage at output pin 212 (OUTPUT_{HI}).

For example, assume the maximum voltage rating of the DUT 116 is +1.8V/−1.0V, the supply voltage of the SMU 101 is 8V, and the FA 104 has a gain of 2 and ±6V of headroom. With a maximum voltage rating of +1.8V, the first voltage pin 140 is set to 1.5V, and the second voltage pin 142 is set to −0.4V. For example, an external supply voltage supplies 1.2V at the first voltage pin 140, and another supplies −0.4V at the second voltage pin 142. In the example operation, sense pin 208 (SENSE_{HI}) gets disconnected (e.g., an open Kelvin connection) from the voltage sense circuitry 112, creating an open-circuit failure that causes the DUT 116 to have infinite resistance, thereby preventing current from flowing through it. As a result, the voltage at output pin 212 (OUTPUT_{HI}) begins to increase to the supply of the SMU 101 (e.g., +8V), because voltage is proportional to resistance. When voltage at the second input (−) of the first comparator 410 exceeds 1.5V (e.g., the voltage set at the first voltage pin 140), the first comparator 410 provides approximately 0V. Assume that the FA 104 properly provides 1.5V to the first input 132 of the DUT protection circuitry 406 but wants to drive more voltage at the first input 132 due to the open Kelvin connection, to compensate for not sensing any voltage at the sense pin 208 (SENSE_{HI}). For example, when sense pin 208 (SENSE_{HI}) is disconnected, the voltage sense circuitry 112 does not measure the voltage across the DUT 116 and provides a low signal to the second input (−) of the FA 104 indicating as such. However, the 0V provided by the first comparator 410 causes the first diode 402 to turn on and conduct current due to the higher voltage applied to the input of the first diode 402 (e.g., +1.5V and increasing) relative to the voltage applied to the output of the first diode 402 (e.g., 0V). The first diode 402 sends excess current to the first comparator 410 and clamps the voltage at V_{CLAMP} node to 1.5V. The amplifier 408 drives the voltage at output pin 212 (OUTPUT_{HI}) to be equivalent to the voltage at V_{CLAMP}.

In FIG. 4, the second comparator 412 operates similarly to clamp the voltage at V_{CLAMP} node when output pin 212 (OUTPUT_{HI}) drops below the voltage at the second voltage pin 142. For example, when the second comparator 412 determines that the voltage at output pin 212 (OUTPUT_{HI}) is less than the voltage at the second voltage pin 142, second comparator 412 provides a high voltage signal to the input of the second diode 404. In some examples, this high voltage signal causes the second diode 404 to turn on and conduct current, thereby increasing the voltage at V_{CLAMP}, which increases an output signal of the amplifier 408 and, thus, increases the voltage at output pin 212 (OUTPUT_{HI}).

For example, assume the second sense pin 210 (SENSE_{LO}) becomes disconnected and the voltage at output pin 212 (OUTPUT_{HI}) drops below −1V. When voltage at the second input (−) of the second comparator 412 decreases below −1V (e.g., the voltage set at the second voltage pin 142), the second comparator 412 provides a high signal. Assume that the FA 104 properly provides −1V to the first input 132 of the DUT protection circuitry 406 but wants to drive less voltage at the first input 132 due to the open Kelvin connection, to compensate for not sensing any voltage at the second sense pin 210. However, the high signal provided by the second comparator 412 causes the second diode 404 to turn on and conduct current due to the higher voltage applied to the input of the second diode 404 (e.g., −1V and decreasing) relative to the voltage applied to the output of the second diode 404 (e.g., high signal). The second diode 404 sends excess current to the second comparator 412 and clamps the voltage at V_{CLAMP} node to −1V. The amplifier 408 drives the voltage at output pin 212 (OUTPUT_{HI}) to be equivalent to the voltage at V_{CLAMP}.

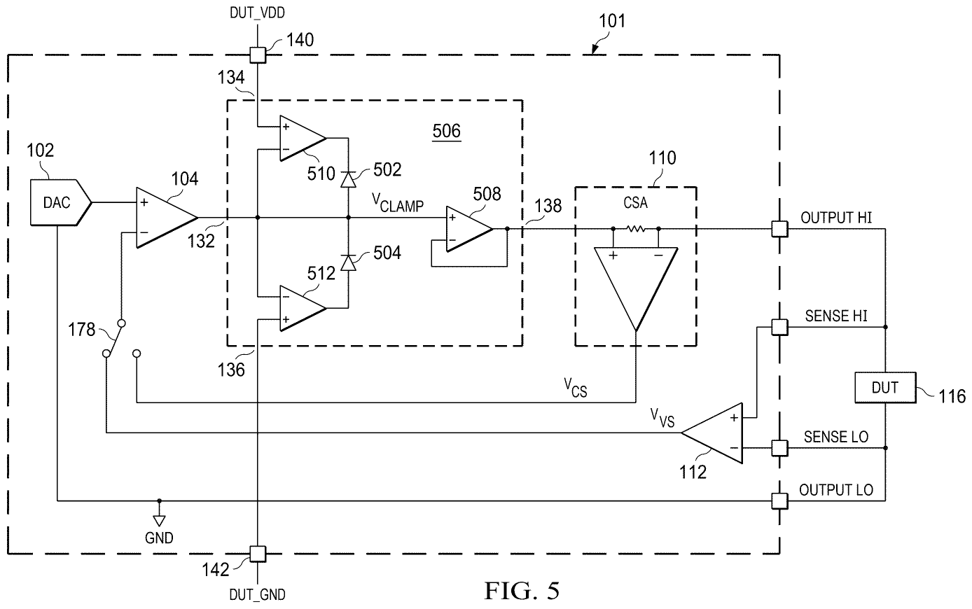

FIG. 5 is a schematic of an example third implementation of the DUT protection circuitry 106 of FIG. 2. In the example of FIG. 5, the SMU 101 includes the DAC 102 of FIG. 1, the FA 104 of FIG. 1, the current sense amplifier circuitry 110 of FIG. 1, the voltage sense circuitry 112 of FIG. 1, the DUT 116 of FIG. 1, the force voltage/current switch 178 of FIG. 1, and an example DUT protection circuitry 506. The DUT protection circuitry 506 of FIG. 5 includes an example first diode 502, an example second diode 504, an example amplifier 508, an example first comparator 510, and an example second comparator 512.

The first diode 502 of FIG. 5 includes an input (anode) and an output (cathode), the second diode 504 of FIG. 5 includes an input and an output, and the amplifier 508 of FIG. 5 includes a first input, a second input, and an output. The first comparator 510 includes a first input, a second input, and an output. The second comparator 512 includes a first input, a second input, and an output.

The input of the first diode 502 is coupled to the output of the FA 104. The output of the first diode 502 is coupled to the output of the first comparator 510. The input of the second diode 504 is coupled to the output of the second comparator 512. The output of the second diode 504 is coupled to the output of the FA 104 and to the input of the first diode 502 at node V_{CLAMP}. The first input (+) of the amplifier 508 is coupled to the output of the FA 104, to the input of the first diode 502, and to the output of the second diode 504. The second input (−) of the amplifier 508 is coupled to the output of the amplifier 508. The output of the amplifier 508 is coupled to the output pin 212 (OUTPUT_{HI}). The first input (+) of the first comparator 510 is coupled to the first voltage pin 140. The second input (−) of the first comparator 510 is coupled to the output of the FA 104 and to the input 132 of the DUT protection circuitry 506. The output of the first comparator 510 is coupled to the output (cathode) of the first diode 502. The first input (+) of the second comparator 512 is coupled to the second voltage pin 142. The second input (−) of the second comparator 512 is coupled to the output of the FA 104 and to the input 132 of the DUT protection circuitry 506. The output of the second comparator 512 is coupled to the input (anode) of the second diode 504.

The third implementation of the DUT protection circuitry 506 operates to sense a voltage at the output of the FA 104 and clamp that voltage to the voltage set by the external protection voltage (e.g., the voltage at the first voltage pin 140 and the voltage at the second voltage pin 142). The amplifier 508 operates in a similar or same manner as the amplifier 408 of FIG. 4. For example, the amplifier 508 is a unity gain buffer that buffers the output signal of the FA 104 and prevents the FA 104 from being loaded by the DUT 116. The first input (+) of the first comparator 510 and the first input (+) of the second comparator 512 are voltage setpoints, set by the first voltage pin 140 and second voltage pin 142, respectively. As such, when the first comparator 510 and the second comparator 512 compare the voltage at the output of the FA 104 to the respective voltage setpoints, the first comparator 510 and second comparator 512 will provide a voltage signal indicative of a result of the comparison.

For example, assume the maximum voltage rating of the DUT 116 is +1.5V/−1, and the voltage setpoint at the first voltage pin 140 is +1.5V and the voltage setpoint at the second voltage pin 142 is −0.4V. When the first comparator 510 determines that the voltage at the output of the FA 104 is greater than the setpoint voltage (e.g., +1.5V) at the first voltage pin 140, the first comparator 510 provides a low voltage signal (e.g., 0V) to the output (cathode) of the first diode 502, indicating that the voltage at the second input (−) is greater than the voltage at the first input (+). In some examples, this low voltage signal causes the first diode 502 to turn on and conduct current, thereby decreasing the voltage at the output of the FA 104 and first input (+) of the amplifier 508. The amplifier 508 to drives the decreased voltage (e.g., 1.5V or less) to the input of the DUT 116, protecting the DUT 116 from potential EOS. For example, when the first diode 502 turns on, the voltage at V_{CLAMP} node in excess of the voltage setpoint (e.g., 1.5V) is lowered as current is flowing through the first diode 502 into the first comparator 510. In some examples, the first comparator 510 provides a high voltage signal to the output of the first diode 502 to turn the first diode 502 off when the output signal of the FA 104 is not greater than the voltage setpoint (e.g., 1.5V) at the first voltage pin 140. For example, when the voltage at the second input (−) of the first comparator 510 is less than or approximately equal to the voltage setpoint at the first input (+) of the first comparator 510 (e.g., voltage at second input of 510 is 1.49V), the first comparator 510 provides a high voltage signal to the output of the first diode 502. The output of the first comparator 510 is greater than the voltage setpoint, thereby the voltage at the output (cathode) of the first diode 502 is greater than the voltage at the input (anode) of the first diode 502, causing the first diode 502 to turn off.

In another example, when the second comparator 512 determines that the voltage at the output of the FA 104 is less than the voltage at the second voltage pin 142 (e.g., <−0.4V), the second comparator 512 provides a high voltage signal to the input (anode) of the second diode 504, indicating that the voltage at the second input (−) is less than the voltage at the first input (+). In some examples, this high voltage signal causes the second diode 504 to turn on and conduct current, thereby increasing the voltage at the output of the FA 104 and the first input (+) of the amplifier 508. The amplifier 508 drives the increased voltage (e.g., −1V or greater) to the input of the DUT 116, protection the DUT 116 from potential EOS. For example, when the second diode 504 turns on, the voltage at V_{CLAMP} node is increased as more current is sent through the second diode 504 into the V_{CLAMP} node. In some examples, the second comparator 512 provides a low voltage signal to the input of the second diode 504 to turn the second diode 504 off when the output signal of the FA 104 is not less than the voltage setpoint at the second voltage pin 142. For example, when the voltage at the second input (−) of the second comparator 512 is greater than or approximately equal to the voltage setpoint at the first input (+) of the second comparator 512, the second comparator 512 provides a low voltage signal to the input of the second diode 504, turning off the second diode 504.

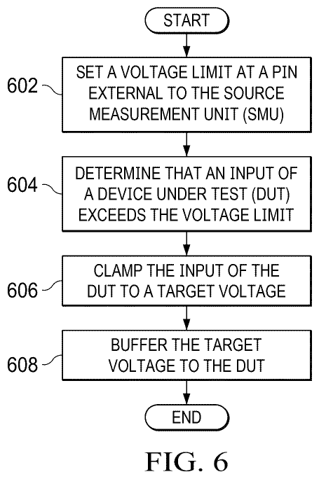

FIG. 6 is a flowchart representative of example operations 600 that may be performed by the DUT protection circuitry of FIGS. 2-5. The operations 600 begin at block 602, where a voltage limit is set at a pin external to the SMU 101 (FIG. 2). For example, the first voltage pin 140 (FIG. 2) is provided with a first voltage equivalent to the maximum voltage rating of the DUT 116 (FIG. 2), equivalent to the maximum voltage rating of the DUT 116 plus the voltage of a diode drop (e.g., 0.6V), etc., and the second voltage pin 142 (FIG. 2) is provided with a second voltage equivalent to the lowest maximum voltage rating of the DUT 116 (FIG. 2), equivalent to the lowest maximum voltage rating of the DUT 116 minus the voltage of a diode drop (e.g., 0.6V), etc.

At block 604, the DUT protection circuitry 106 (FIG. 2) determines that an input signal of the DUT 116 (FIG. 2) exceeds the voltage limit. For example, the DUT protection circuitry 306 (FIG. 3) includes first and second diodes 302, 304 (FIG. 3) that turn on when the output signal of the FA 104, which is buffered to the input of the DUT 116, is greater than the voltage limit at first voltage pin 140 or less than the voltage limit at second voltage pin 142. In another example, the DUT protection circuitry 406 (FIG. 4) includes first and second comparators 410, 412 (FIG. 4) that compare the voltage at the output pin 212 (OUTPUT_{HI}) to the voltage limit and turn on respective diodes 402, 404 (FIG. 4) when the voltage at the input of the DUT 116 exceeds the voltage limits. In another example, the DUT protection circuitry 506 includes first and second comparators 510, 512 (FIG. 5) that compare the voltage at the output of the FA 104, which is buffered to the input of the DUT 116, to the voltage limit and turn on respective diodes 502, 504 (FIG. 5) when the voltage at the output of the FA 104 exceeds the voltage limits.

At block 606, the DUT protection circuitry 106 clamps the voltage at the input of the DUT 116 to a target voltage. For example, the first diode 302 and second diode 304 of the DUT protection circuitry 306 clamp the voltage at the output of the FA 104 to a value that is equivalent to the voltage limit set at the pins 140, 142 plus the diode drop voltage (0.6V). In another example, the first diode 402 and second diode 404 clamp the voltage at the output of the FA 104 to a target voltage determined by the output signal of the respective first and second comparators 410, 412. In another example, the first diode 502 and second diode 504 clamp the output signal of the FA 104 to a target voltage determined by the output signal of the respective first and second comparators 510, 512.

At block 608, the DUT protection circuitry 106 buffers the target voltage to the DUT 116. For example, the clamped target voltage is at first input (+) of the amplifier 308 (FIG. 3), and the amplifier 308 provides the target voltage to the input of the DUT 116. In another example, the clamped target voltage is at first input (+) of the amplifier 408 (FIG. 4), and the amplifier 408 provides the target voltage to the input of the DUT 116. In another example, the clamped target voltage is at first input (+) of the amplifier 508 (FIG. 5), and the amplifier 508 provides the target voltage to the input of the DUT 116.

The operations 600 end when the DUT protection circuitry 106 does not detect an input of the DUT 116 exceeding the voltage limit.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and things, the phrase “at least one of A and B” refers to implementations including any of (1) at least one A, (2) at least one B, or (3) at least one A and at least one B. Similarly, as used herein in the context of describing structures, components, items, objects and things, the phrase “at least one of A or B” refers to implementations including any of (1) at least one A, (2) at least one B, or (3) at least one A and at least one B. As used herein in the context of describing the performance or execution of processes, instructions, actions, activities, etc., the phrase “at least one of A and B” refers to implementations including any of (1) at least one A, (2) at least one B, or (3) at least one A and at least one B. Similarly, as used herein in the context of describing the performance or execution of processes, instructions, actions, activities, etc., the phrase “at least one of A or B” refers to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Also, although individual features may be included in different examples or claims, these may possibly be combined, and the inclusion in different examples or claims does not imply that a combination of features is at least one of not feasible or advantageous.

As used herein, connection references (e.g., attached, coupled, connected, and joined) may include intermediate members between the elements referenced by at least one of the connection reference or relative movement between those elements unless otherwise indicated. As such, connection references do not necessarily infer that two elements are directly connected or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, or ordering in any way, but are merely used as at least one of labels or arbitrary names to distinguish elements for ease of understanding the described examples. In some examples, the descriptor “first” may be used to refer to an element in the detailed description, while the same element may be referred to in a claim with a different descriptor such as “second” or “third.” In such instances, such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to at least one of manufacturing tolerances or other real-world imperfections. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time +1 second.

As used herein, the phrase “in communication,” including variations thereof, encompasses one of or a combination of direct communication or indirect communication through one or more intermediary components, and does not require direct physical (e.g., wired) communication or constant communication, but rather also includes selective communication at least one of periodic intervals, scheduled intervals, aperiodic intervals, or one-time events.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., at least one of programmed or hardwired) at a time of manufacturing by a manufacturer to at least one of perform the function or be configurable (or re-configurable) by a user after manufacturing to perform the function/or other additional or alternative functions. The configuring may be through at least one of firmware or software programming of the device, through at least one of a construction or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

In the description and claims, described “circuitry” may include one or more circuits. A circuit or device that is described herein as including certain components may instead be adapted to be coupled to those components to form the described circuitry or device. For example, a structure described as including one or more semiconductor elements (such as transistors), one or more passive elements (such as one of or a combination of resistors, capacitors, or inductors), or one or more sources (such as voltage and/or current sources) may instead include only the semiconductor elements within a single physical device (e.g., at least one of a semiconductor die or integrated circuit (IC) package) and may be adapted to be coupled to at least some of the passive elements or the sources to form the described structure either at a time of manufacture or after a time of manufacture, for example, by at least one of an end-user or a third-party.

Circuits described herein are reconfigurable to include the replaced components to provide functionality at least partially similar to functionality available prior to the component replacement. Components shown as resistors, unless otherwise stated, are generally representative of any one or more elements coupled in at least one of series or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and some features illustrated as being internal to the integrated circuit may be incorporated outside of the integrated. As used herein, the term “integrated circuit” means one or more circuits that are at least one of: (i) incorporated in/over a semiconductor substrate; (ii) incorporated in a single semiconductor package; (iii) incorporated into the same module; or (iv) incorporated in/on the same printed circuit board.

Uses of the phrase “ground” in the foregoing description include at least one of a chassis ground, an Earth ground, a floating ground, a virtual ground, a digital ground, a common ground, or any other form of ground connection applicable to, or suitable for, the teachings of this description. Unless otherwise stated, “about,” “approximately,” or “substantially” preceding a value means +/−10 percent of the stated value, or, if the value is zero, a reasonable range of values around zero.

Modifications are possible in the described embodiments, and other embodiments are possible, within the scope of the claims.

From the foregoing, it will be appreciated that example systems, apparatus, articles of manufacture, and methods have been described that prevent electrical over-voltage stress (EOS) on a device under test (DUT) having a maximum voltage rating that is below a supply voltage of a source measurement unit. For example, a source measurement unit (SMU) is provided with a device under test protection circuitry and an external protection voltage that operates to clamp the input to the DUT to some target voltage that does not exceed the maximum voltage rating of the DUT. Described systems, apparatus, articles of manufacture, and methods are also directed to one or more improvement(s) in the operation of a machine such as a computer or other electronic, electromechanical, or mechanical device.

What is claimed is:

1. An electrical device comprising:
an amplifier having an input and an output;
a voltage pin;
an output pin;
protection circuitry having an input, a terminal, and an output, the input of the protection circuitry coupled to the output of the amplifier, the terminal of the protection circuitry coupled to the voltage pin, and the output of the protection circuitry coupled to the output pin; and
sense circuitry having an input coupled to a pin of the electrical device and an output coupled to the input of the amplifier.

2. The electrical device of claim 1, wherein the amplifier is a first amplifier, the protection circuitry includes:
a diode having an anode and a cathode, the anode of the diode coupled to the output of the first amplifier and the cathode of the diode coupled to the terminal of the protection circuitry and to the voltage pin; and
a second amplifier having a first input, a second input, and an output, the first input of the second amplifier coupled to the anode of the diode and the output of the first amplifier, the second input of the second amplifier coupled to the output of the second amplifier, and the output of the second amplifier coupled to the output pin.

3. The electrical device of claim 2, wherein the second amplifier is a unity gain buffer.

4. The electrical device of claim 2, wherein the diode is a first diode, the voltage pin is a first voltage pin, the electrical device further including:
a second voltage pin; and
a second diode having an anode and a cathode, the anode of the second diode coupled to the second voltage pin and the cathode of the second diode coupled to the output of the first amplifier, the anode of the first diode, and the first input of the second amplifier.

5. The electrical device of claim 4, wherein the second voltage pin is structured to be coupled to an external voltage supply different than a voltage supply of the first amplifier and second amplifier.

6. The electrical device of claim 1, wherein the voltage pin is structured to be coupled to a first supply voltage different from a second supply voltage of the amplifier.

7. The electrical device of claim 6, wherein the first supply voltage is lower than the second supply voltage.

8. The electrical device of claim 1, wherein the amplifier is a first amplifier, the protection circuitry includes:
a comparator having a first input, a second input, and an output, the first input of the comparator coupled to the voltage pin, the second input of the comparator coupled to the output of the first amplifier;
a diode having an anode and a cathode, the anode of the diode coupled to the output of the first amplifier and to the second input of the comparator, the cathode of the diode coupled to the output of the comparator; and
a second amplifier having a first input, a second input, and an output, the first input of the second amplifier coupled to the output of the first amplifier, the anode of the diode, and to the second input of the comparator, the second input of the second amplifier coupled to the output of the second amplifier, and the output of the second amplifier coupled to the output pin.

9. The electrical device of claim 8, wherein the voltage pin is a first voltage pin, the comparator is a first comparator, and the diode is a first diode, the protection circuitry includes:
a second comparator having a first input, a second input, and an output, the first input of the second comparator coupled to the output of the first amplifier and to the first input of the second amplifier, the second input of the second comparator coupled to a second voltage pin; and
a second diode having an anode and a cathode, the anode of the second diode coupled the output of the second comparator, the cathode of the second diode coupled to the output of the first amplifier, the anode of the first diode, and to the first input of the second amplifier.

10. The electrical device of claim 1, wherein the amplifier is a first amplifier, the protection circuitry includes:
a comparator having a first input, a second input, and an output, the first input of the comparator coupled to the voltage pin, the second input of the comparator coupled to the output of the protection circuitry;
a diode having an input and an output, the anode of the diode coupled to the output of the first amplifier, the cathode of the diode coupled to the output of the comparator; and
a second amplifier having a first input, a second input, and an output, the first input of the second amplifier coupled to the output of the first amplifier and to the anode of the diode, the second input of the second amplifier coupled to the output of the second amplifier, and the output of the second amplifier coupled to the second input of the comparator and to the output pin.

11. The electrical device of claim 10, wherein the voltage pin is a first voltage pin, the comparator is a first comparator, and the diode is a first diode, the protection circuitry includes:
a second comparator having a first input, a second input, and an output, the first input of the second comparator coupled to output of the second amplifier, the second input of the second comparator coupled to a second voltage pin; and
a second diode having an anode and a cathode, the anode of the second diode coupled to the output of the second comparator, the cathode of the second diode coupled to the output of the first amplifier, to the anode of the first diode, and to the first input of the second amplifier.

12. An electrical device comprising:
a first amplifier having an input and an output;
a voltage pin and an output pin;
a diode having an anode and a cathode, the cathode of the diode coupled to the voltage pin;
a second amplifier having a first input, a second input, and an output, the first input of the second amplifier coupled to the anode of the diode and to the output of the first amplifier, the second input of the second amplifier coupled to the output of the second amplifier, and the output of the second amplifier coupled to the output pin; and
sense circuitry having an input coupled to a pin of the electrical device and an output coupled to the input of the first amplifier.

13. The electrical device of claim 12, wherein the voltage pin is structured to be coupled to a first supply voltage different from a second supply voltage of the first and second amplifiers.

14. The electrical device of claim 12, wherein the diode is a first diode, the voltage pin is a first voltage pin, the electrical device further including:
a second voltage pin; and
a second diode having an anode and a cathode, the anode of the second diode coupled to the second voltage pin and the cathode of the second diode coupled to the output of the first amplifier, to the first input of the second amplifier, and to the anode of the first diode.

15. The electrical device of claim 14, wherein the second voltage pin is structured to be coupled to an external voltage supply different than a voltage supply of the first and second amplifiers.

16. The electrical device of claim 12, wherein the second amplifier is a unity gain buffer.

17. An electrical device having a first voltage pin, a second voltage pin, an output pin, and a sense pin, the electrical device comprising:
a first amplifier having an input and an output;
a first diode having an anode and a cathode, the cathode of the first diode coupled to the first voltage pin;
a second diode having an anode and a cathode, the anode of the second diode coupled to the second voltage pin and the cathode of the second diode coupled to the anode of the first diode;
a second amplifier having a first input, a second input, and an output, the first input of the second amplifier coupled to the anode of the first diode, to the cathode of the second diode, and to the output of the first amplifier, the second input of the second amplifier coupled to the output of the second amplifier, and the output of the second amplifier coupled to the output pin;
current sense circuitry having an input and an output, the input of the current sense circuitry coupled to the output of the second amplifier, the output of the current sense circuitry coupled to the output pin; and
voltage sense circuitry having an input and an output, the input of the voltage sense circuitry coupled to the sense pin, the output of the voltage sense circuitry coupled to the input of the first amplifier.

18. The electrical device of claim 17, wherein the first voltage pin is structured to be coupled to a first supply voltage different from a second supply voltage of the first and second amplifiers, and the second voltage pin is structured to be coupled to an external voltage supply different than a voltage supply of the first and second amplifiers.

19. The electrical device of claim 17, wherein the first amplifier is a force amplifier and the second amplifier is a unity gain buffer.

20. The electrical device of claim 17, wherein the cathode of the first diode is structured to be coupled to the first voltage pin, the anode of the second diode is structured to be coupled to the second voltage pin, the electrical device further including:
a first comparator having a first input, a second input, and an output, the first input of the first comparator coupled to the first voltage pin, the second input of the first comparator coupled to the output of the current sense circuitry, and the output of the first comparator coupled to the cathode of the first diode; and
a second comparator having a first input, a second input, and an output, the first input of the second comparator coupled to second voltage pin, the second input of the second comparator coupled to the output of the current sense circuitry, and the output of the second comparator coupled to the anode of the second diode.

21. The electrical device of claim 17, wherein the cathode of the first diode is structured to be coupled to the first voltage pin, the anode of the second diode is structured to be coupled to the second voltage pin, the electrical device further including:
a first comparator having a first input, a second input, and an output, the first input of the first comparator coupled to the first voltage pin, the second input of the first comparator coupled to the output of the first amplifier and the first input of the second amplifier, and the output of the first comparator coupled to the cathode of the first diode; and
a second comparator having a first input, a second input, and an output, the first input of the second comparator coupled to second voltage pin, the second input of the second comparator coupled to the output of the first amplifier and to the first input of the second amplifier, and the output of the second comparator coupled to the anode of the second diode.
